(19) United States
(12) Patent Application Publication
(10) Pub. No.: US 2003/0077545 A1
(43) Pub. Date: Apr. 24, 2003

(54) Multi-gap mask, method for manufacturing same and method for manufacturing component part by using same

(75) Inventor: Yoshitaka Kawanishi, Tokyo (JP)

Correspondence Address: SUGHRUE MION, PLLC, 2100 PENNSYLVANIA AVENUE, N.W., WASHINGTON, DC, 20037, US

(73) Assignee: NEC PLASMA DISPLAY CORPORATION

(21) Appl. No.: 10/274,410

(22) Filed: Oct. 21, 2002

(30) Foreign Application Priority Data
Oct. 22, 2001 (JP) 323847/2001

(51) Int. Cl. G03F 7/00

(52) U.S. Cl. 430/320; 216/41

(57) ABSTRACT

A multi-gap mask is provided which enables worked patterns each having a different height to be concurrently and collectively formed. In the multi-gap mask, first and second mask patterns are formed which are fixed on/over a surface of an object to be worked when sandblasting is performed on the surface of the object to be worked and each of which has a different gap from the surface of the object to be worked. The first mask pattern is made up of a plurality of metal wires and a second mask pattern is made up of a plurality of a rectangular-parallelepiped-shaped photosensitive emulsion. By using the multi-gap mask having a gap from the surface of the object to be worked and a velocity distribution of a viscous fluid in a gap region, a worked pattern having various depths can be concurrently and collectively fabricated without an increase in numbers of man-hours.

### BACKGROUND OF THE INVENTION

1. Field of the Invention

The present invention relates to a multi-gap mask, a method for manufacturing the same and a method for manufacturing a component part by using the same, and more particularly to the multi-gap mask to be placed in a fixed manner on a work surface while the work surface is worked on by powerfully delivering a viscous fluid including an abrasive compound, the method for manufacturing the multi-gap mask and a method for manufacturing the component part by using the multi-gap mask. The present invention is preferably used, for example, for working partition walls (ribs) to divide a display cell (discharging gas space) in a plasma display panel.

The present application claims priority of Japanese Patent Application No.2001-323847 filed on Oct. 22, 2001, which is hereby incorporated by reference.

2. Description of the Related Art

As typical polishing technique using a viscous fluid, sandblast of a solid-gas two-phase flow using air or an abrasive compound is generally used. A typical worked product obtained by pattern working using the sandblast technique after a master pattern has been formed on an object to be worked is a discharging cell pattern formed on a substrate of a display panel.

A method for forming worked patterns each having a different height on a substrate of a display panel by using the sandblast process is disclosed in Japanese Patent Application Laid-open No. 2000-123747, in which, after a material to be worked for a worked pattern having a small height on a substrate have been formed following repeated formation of a material to be worked for a worked pattern having a greater height and a mask pattern on a substrate, sandblasting is performed to produce a worked pattern having a large height and a worked pattern having a small height. Another method for forming a worked pattern having a small height and a worked pattern having a large height is disclosed in Japanese Patent Application Laid-open No. Hei 7-45191 in which, after a material to be worked and a mask pattern for a worked pattern having a small height have been formed on a substrate of a display panel, a material to be worked for a worked pattern having a greater height and then a mask pattern having a large height is formed in a manner that it does not overlap the mask pattern having a small height and sandblasting is performed to produce a worked pattern having a small height and a worked pattern having a large height.

Another method for forming worked patterns each having a different height on a substrate of a display panel by repeatedly performing a sandblast process two or more times is disclosed in Japanese Patent Application Laid-open No. Hei 7 -282730 in which, after a mask pattern has been formed, the sandblasting and drying are repeated to form a worked pattern having a small height and a worked pattern having a large height.

Still another method for forming worked patterns each having a different height on a substrate of a display panel by performing a sandblast process is available in which, after a worked pattern having a small height has been formed by using a photosensitive glass paste, a material to be worked and a mask pattern is formed and then a sandblast process is performed to form a worked pattern having a small height and a worked pattern having a large height.

Moreover, a method for forming a worked pattern having a small height whose cross sectional shape is disclosed in Japanese Patent Application Laid-open No. Hei 10-321148 in which a worked pattern having a small height and a worked pattern having a large height are formed by using a transfer sheet.

Still another method for forming a worked pattern having a large height and a worked pattern having a small height is disclosed in Japanese Patent Application Laid-open No. Hei 11-317170 in which discharged space is formed by having a worked pattern having a large height and a worked pattern having a small height obtained by adjusting a shape using a printing method crossing in parallel crosses. However, conventional technology has the following problems.

A method in which a material to be worked and a mask pattern for a worked pattern having a small height and a material to be worked and a mask pattern for a worked pattern having a large height are stacked in layers presents a problem in that, since a process of coating with the material to be worked and a process of forming the mask pattern are repeated twice, an increase in a number of man-hours is unavoidable. Additionally, there is another problem in that a worked pattern suffers damage caused by a mask of a worked pattern having a small height at a time of peeling off a mask pattern for a worked pattern having a small height and, as a result, a defect occurs. At this point, another problem arises in that, even if a mask pattern is removed by a baking process, a failure occurs due to a remainder existing after being baked.

The method disclosed in Japanese Patent Application Laid-open No. Hei 7-282730 in which, after the mask pattern has been formed, the sandblasting and drying are alternately repeated to form a worked pattern having a small height and a worked pattern having a large height, presents a problem in that, since a process of coating with a material to be worked, a process of forming a mask pattern and a process of polishing using a sandblast technique have to be repeated, an increase in a number of man-hours is unavoidable and a positional adjustment becomes difficult.

A method in which, after a worked pattern having a small height on a substrate has been formed using a photosensitive glass paste, a material to be worked and a mask pattern are formed to produce a worked pattern having a small height and a worked pattern having a large height by performing the sandblast process, presents a problem in that a number of man-hours for pattern formation caused by use of a photosensitive glass paste increases and mask positioning becomes difficult.

Thus, all the conventional technologies present a problem in that the number of man-hours required for the above processes increases and a rise in costs occurs.

A method for forming a worked pattern (being called a “transfer method”) disclosed in Japanese Patent Application Laid-open No. Hei 10-321148 in which the worked pattern whose cross sectional shape has a tilt is formed using a transfer sheet, also presents a problem in that, since formation of a tilt portion in a metal mold used to manufacture a transfer sheet is difficult, it is impossible to fabricate the worked pattern having a complicated shape.

The method disclosed in Japanese Patent Application Laid-open No. Hei 11-317170 in which discharged space is formed by causing a worked pattern having a large height and a worked pattern having a small height obtained by adjusting a shape using a printing method to be crossed in parallel crosses, also presents a problem in that, since printing and drying processes have to be repeated several ten times by using plates for printing of, at least, two or more types, it is difficult to obtain positional accuracy and a rise in costs occurs due to increased numbers of man-hours.

### SUMMARY OF THE INVENTION

In view of the above, it is an object of the present invention to provide a multi-gap mask which enables a worked pattern having a small height and a worked pattern having a large height to be simply formed, a method of working by using the multi-gap mask and a method for manufacturing the multi-gap mask.

According to a first aspect of the present invention, there is provided a multi-gap mask including:

at least two mask patterns to be fixed on a surface of an object to be worked while working is performed on the surface of the object to be worked by sending a blast of a viscous fluid including an abrasive compound and each having a different gap from the surface of the object to be worked.

In the foregoing, a preferable mode is one wherein at least one of at least two mask patterns has the gap being zero from the surface of the object to be worked.

Also, a preferable mode is one that wherein is made up of first and second mask patterns each having the different gap wherein the first mask pattern has a shape of a plurality of straight lines being parallel to one another and wherein the second mask pattern intersects the first mask pattern and has a shape of a plurality of straight lines being parallel to one another.

Also, a preferable mode is one wherein a whole or a part of shapes having the plurality of straight lines is of a circular cylindrical shape.

According to a second aspect of the present invention, there is provided a method of working including:

a step of fixing a multi-gap mask described above on a surface of an object to be worked;

a step of performing work on the surface of the object to be worked by sending a blast of a viscous fluid including an abrasive compound; and

a step of using a vortex region of the viscous fluid occurring on a side of the surface of the object to be worked of the multi-gap mask when working is performed on the surface of the object to be worked.

In the foregoing, a preferable mode is one wherein the blast of the viscous fluid is sent to the surface of the object to be worked in a slant manner when working is performed on the surface of the object to be worked.

According to a third aspect of the present invention, there is provided a method for manufacturing a multi-gap mask described above, the method including:

a step of stretching wires having a set height and direction in a photosensitive emulsion;

a step of forming a three-dimensional mask pattern by performing a drying process, exposure process, and developing process on the photosensitive emulsion.

According to a fourth aspect of the present invention, there is provided a method for manufacturing a multi-gap mask described above, the method including:

a step of sticking a dry film photoresist to both sides of a film;

a step of performing exposure and development on each of the dry film photoresists to produce a different pattern; and

a step of forming a three-dimensional mask pattern by performing etching on the film using the dry film photoresists as a mask.

According to a fifth aspect of the present invention, there is provided a method for manufacturing a multi-gap mask described above, the method including:

a step of forming a photoresist film on a mesh film; and

a step of forming a three-dimensional mask pattern by performing exposure and development on the photoresist film using a straight-line shaped mask pattern.

With the above configurations, by formation of at least two mask patterns each having a different gap from the surface of the object to be worked, since a flow of a viscous fluid including an abrasive compound is changed depending on an amount of the gap, it is possible to form worked patterns each having a different height at a same time.

With another configuration as above, since, by using a vortex region of a viscous fluid including the abrasive compound, a velocity of the viscous fluid is changed remarkably inside and outside of the vortex region, worked patterns each having a different height can be easily formed.

With another configuration as above, since, by stretching wires in a photosensitive emulsion and by drying the photosensitive emulsion and by performing exposure and development, a height and a direction are changed, three-dimensional configurations are easily formed. Moreover, the photosensitive emulsion can be used not only as a fixing material of the wires but also as a mask. Also, by using the photosensitive emulsion, patterning is made easy and a multi-gap mask being excellent in a mass production characteristic can be provided.

With still another configuration, by sticking the DFR to both sides of the film, by performing exposure and development on the DFR to produce a different pattern and by performing etching on the film using the DFR as a mask, different patterns can be formed on both sides by one time etching process and, by having a common pattern region of the pattern on both sides of the film be pierced, the multi-gap mask can be formed. Moreover, a photoresist used as a mask for etching the film can be employed as a mask serving as a sandblast-proof member.

With still another configuration, by forming a photoresist film on a mesh film and by performing exposure and development on the photoresist film to produce a straight-line shaped mask pattern and to form a three-dimensional mask pattern, since a photoresist pattern having a pattern being different from the mesh pattern can be formed, it is easy to form a three-dimensional configuration of the mask. Moreover, the mesh film contributes to stability in shapes and dimensions of the multi-gap mask and the photoresist film has a compound effect to improve the sandblast-proof characteristic. Also, a formation method of a mesh using the etching technique and formation method of the pattern using a photoresist film, since the multi-gap mask can be easily provided which is excellent in dimensional accuracy using an ordinary exposure and development technologies, is excellent in mass production characteristics.

With still another configuration, in the polishing work using a viscous fluid, by employing the multi-gap mask having a gap from a surface of an object to be worked and by using a velocity distribution of the viscous fluid in the gap region, worked patterns each having a depth can be formed without an increase in numbers of man-hours. Also, by using the metal wires and photosensitive emulsion, multi-gap masks each having a gap from a surface of the object to be worked can be supplied at low costs in a mass production manner. Furthermore, by performing etching on the film from both sides using different patterns, multi-gap masks each having a gap from a surface of the object to be worked can be provided at low costs in a mass production manner.

### BRIEF DESCRIPTION OF THE DRAWINGS

The above and other objects, advantages, and features of the present invention will be more apparent from the following description taken in conjunction with the accompanying drawings in which:

FIG. 1 is a diagram for explaining basic principles of the present invention;

FIG. 2A is a diagram explaining an action of a multi-gap mask in a case of a gap being small and FIG. 2B is a diagram explaining an action of the multi-gap mask in a case of the gap being large according to the present invention;

FIG. 3A is a diagram illustrating principles of a working method in a case in which a blast of an abrasive compound is sent from one direction and FIG. 3B is a diagram illustrating principles of a working method in a case in which the blast of the abrasive compound is sent from two directions of the present invention;

FIGS. 4A, 4B, and 4C are perspective views illustrating the multi-gap mask of the present invention and the working method using the same according to a first embodiment of the present invention (process proceeds in an order of FIG. 4A to FIG. 4C);

FIGS. 5A, 5B, and 5C are perspective views illustrating the multi-gap mask of the present invention and the working method using the same according to the first embodiment of the present invention (process proceeds in the order of FIG. 5A to FIG. 5C);

FIGS. 6A, 6B, and 6C are cross-sectional views illustrating a multi-gap mask of the present invention and a working method using the same according to a second embodiment of the present invention (process proceeds in an order of FIG. 6A to FIG. 6C);

FIGS. 7A, 7B, and 7C are cross-sectional views illustrating the multi-gap mask of the present invention and the working method using the same according to the second embodiment of the present invention (process proceeds in the order of FIG. 7A to FIG. 7C);

FIGS. 8A, 8B, and 8C are perspective views illustrating a method of manufacturing the multi-gap mask according to the first embodiment of the present invention (process proceeds in an order of FIG. 8A to FIG. 8C);

FIGS. 9A, 9B, and 9C are perspective views illustrating the method for manufacturing the multi-gap mask according to the first embodiment of the present invention (process proceeds in the order of FIG. 9A to FIG. 9C);

FIGS. 10A and 10B are perspective views showing an other example of the multi-gap mask employed in the first embodiment of the present invention provided in FIGS. 8A, 8B, and 8C and FIGS. 9A, 9B, and 9C;

FIGS. 11A and 11B are diagrams schematically illustrating a method for manufacturing the multi-gap mask according to the second embodiment of the present invention (process proceeds in an order of FIG. 11A to FIG. 11B);

FIGS. 12A and 12B are diagrams schematically illustrating the method for manufacturing the multi-gap mask according to the second embodiment of the present invention (process proceeds in the order of FIG. 12A to FIG. 12B);

FIGS. 13A and 13B are plan views and right side views illustrating a method for manufacturing a multi-gap mask according to a third embodiment of the present invention (process proceeds in an order of FIG. 13A to FIG. 13B); and

FIGS. 14A and 14B are plan views and right side views illustrating the method for manufacturing the multi-gap mask according to the third embodiment (process proceeds in the order of FIG. 14A to FIG. 14B).

### PRINCIPLES OF THE PRESENT INVENTION

Before describing each embodiment of the present invention, principles of the present invention are explained using drawings.

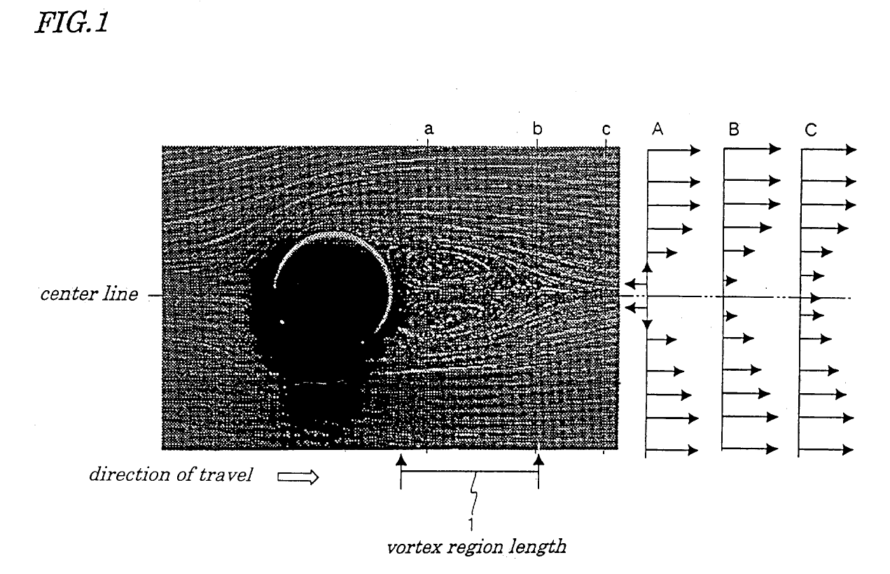

First, FIG. 1 shows a flow around and past a cylinder. A flow pattern is symmetrical right and left with respect to a direction of travel; however, the flow pattern is not symmetrical forward and backward. At a rear (downstream side) of the circular cylinder, a flow separates from the circular cylinder and two symmetrical vortexes (twin vortexes) are formed in a standing manner. In FIG. 1, characters A, B, and C show a distribution of a velocity of flow respectively at points of dashed lines a, b, and c in the photograph. A flow at the point of the dashed line a, since twin vortexes occur at a rear of the circular cylinder, travels backward in a vicinity of a center line and, as the flow parts from the center line, it goes toward the direction of travel and the velocity of flow becomes large. The velocity of the flow at the point of the dashed line b, since the position is a point where the vortex disappears, remains unchanged in a vicinity of the center line and gradually becomes larger as the flow parts from the center line. The velocity of the flow at the point of the dashed line c, since the vortex disappears but an influence by the circular cylinder (caused by a boundary layer or peeling-off) is left, is small and gradually becomes larger as the flow parts from the center line. In the present invention, a distance between a rear portion of the circular cylinder and a position where the vortex disappears is defined as a vortex region length 1.

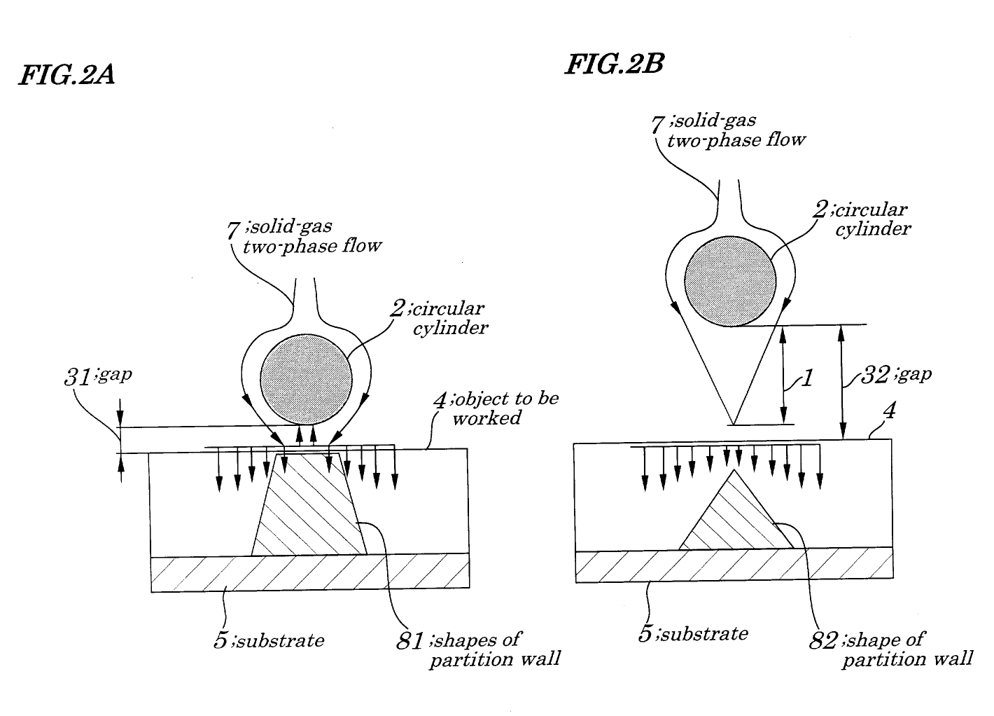

FIGS. 2A and 2B show a difference in shapes of partition walls 81 and 82 to be formed depending on gaps 31 and 32 between circular cylinders 2 and objects to be worked 4 in a sandblast process. The circular cylinder 2 is a mask for a horizontal partition wall (not shown) made up of wires. The object to be worked 4 is formed on a substrate 5. A solid-gas two-phase flow 7 of an abrasive compound and air delivered by pressure jetted from a nozzle is separated in right and left directions on a surface of the upstream side of the circular cylinder 2 and, after having traveled along both side faces of the circular cylinder 2, is parted from the circular cylinder 2. Then, the solid-gas two-phase flow 7, after having parted from the circular cylinder 2, produces the twin vortexes and again travels in an integrated manner.

FIG. 2A shows a case in which the object to be worked 4 is placed at the point a in FIG. 1. At this point, since a vortex of the solid-gas two-phase flow 7 is produced in a vicinity of the center line of the solid-gas two-phase flow 7 around the object to be worked 4, it is impossible to perform polishing on the object to be worked 4. Then, as the flow is parted from the center line of the solid-gas two-phase flow 7, since a velocity of the solid-gas two-phase flow 7 increases, the shape of partition wall 81 obtained by polishing becomes a sharp trapezoid. The gap 31 is, for example, 40 μm.

FIG. 2B shows a case in which the object to be worked 4 is placed at the point c in FIG. 1. At this point, in a vicinity of the center line of the solid-gas two-phase flow 7 in the object to be worked 4, though no change in a direction of the flow caused by the vortex occurs, a distribution of a velocity of the flow exists which is influenced by the circular cylinder 2. As the flow is parted from the center line of the solid-gas two-phase flow 7, since a velocity of the flow of the solid-gas two-phase flow 7 increases, the shape of partition wall 82 obtained by polishing becomes triangular. The gap 32 is larger than a vortex region length 1 and is, for example, 200 μm.

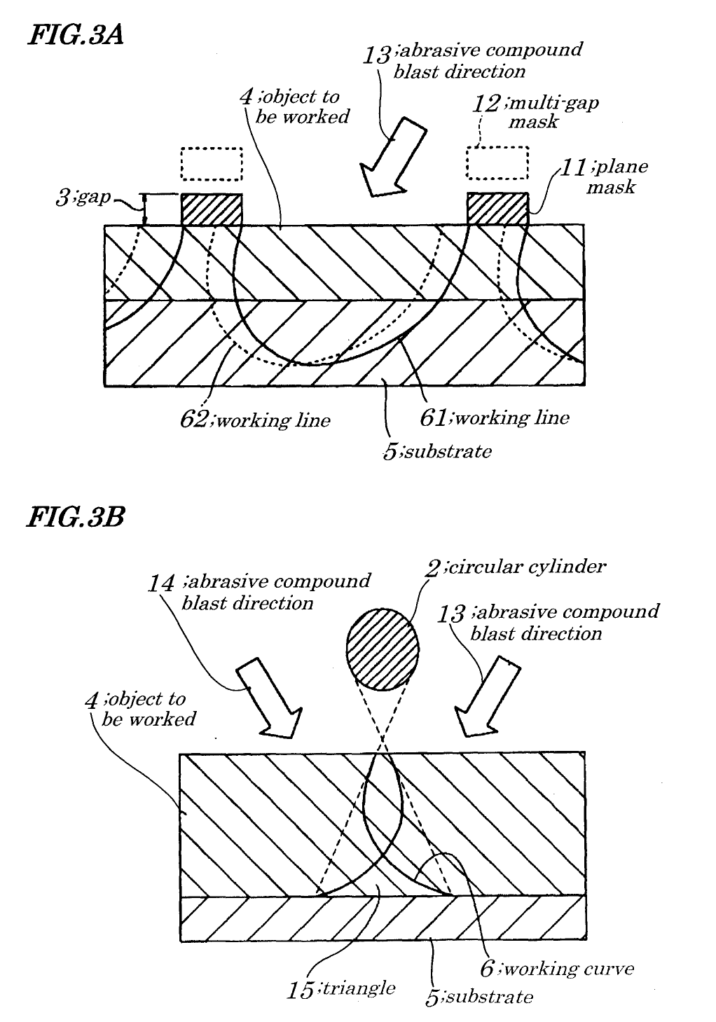

Thus, formation of the partition walls each having a different height using a multi-gap mask 12 (shown in FIG. 3A) is influenced by a distribution of flow at a rear of the multi-gap mask 12. Therefore, in order to form partition walls each having a different height by changing a working rate, all that is needed is a calibration of a gap between the multi-gap mask 12 and the object to be worked 4.

The longer than a vortex region length of the twin vortexes (the gaps 31 and 32 existing at a rear of the multi-gap mask 12) are, since the working rate increases, the shorter a height of the partition wall becomes. The calibration of a height of the partition wall is made possible by changing a length of the twin vortexes by calibrating the gap between the multi-gap mask 12 and the surface of the object to be worked (work surface) 4 and by calibrating a pressure used for delivering the abrasive compound. According to the present invention, by using the multi-gap mask 12 having a different gap, since a region having a different working rate is produced by one-time blasting work, concurrent formation of the partition wall having a different height becomes possible.

In FIG. 3A, a working line 61 (solid line) by tilt processing using a plane mask 11 (conventional mask) and a working line 62 (broken line) by tilt processing using the multi-gap mask 12 (the mask of the present invention) are shown. A slant process represents technology in which the object to be worked 4 is processed in a state in which an abrasive compound blast direction 13 is slant. The plane mask 11 and multi-gap mask 12 are a mask for a horizontal partition wall made up of a DFR (Dry Film photo Resist). A gap 3 between the plane mask 11 and the object to be worked 4 is zero, whereas the gap 3 between the multi-gap mask 12 and the object to be worked 4 is a value exceeding zero. By using the multi-gap mask 12, a shift in the working curve 62 occurs toward a side of a horizontal component in the abrasive compound blast direction 13. By using this shift in the working curve 62 and by performing a uniform slant working, formation of various kinds of partition wall having respectively a different height is made possible.

FIG. 3B is a conceptual diagram illustrating slant working using a multi-gap mask. Working is performed on the object to be worked 4 from both right and left sides of the circular cylinder 2 being a part of the multi-gap mask with abrasive compound blast directions 13 and 14 being slant. Then, since the slant working causes a shift in a working curve 6 to occur in the right and left directions, a cross section of a triangle 15 using an intersecting portion of right and left working curve 6 as its top point is formed. A slant surface of the triangle 15 represents a curve surface along the working curve 6.

The formation of partition walls each having a different height using the slant working technique is caused by a shift in the working curve 6 occurred by making a mask multi-gap, and a height of the partition wall is determined by a gap length and a blast angle of the abrasive compound.

In the present invention, apart or a whole of a cross section of the mask pattern is circular. When the cross section of a mask is circular or half circular, occurrence of a peeled-off flow in a downward direction makes a vortex region smaller. That is, since a gap in the multi-gap mask is made shorter, fabrication of the multi-gap mask is made easy.

### DETAILED DESCRIPTION OF THE PREFERRED EMBODIMENTS

Best modes of carrying out the present invention will be described in further detail using various embodiments with reference to the accompanying drawings.

### First Embodiment

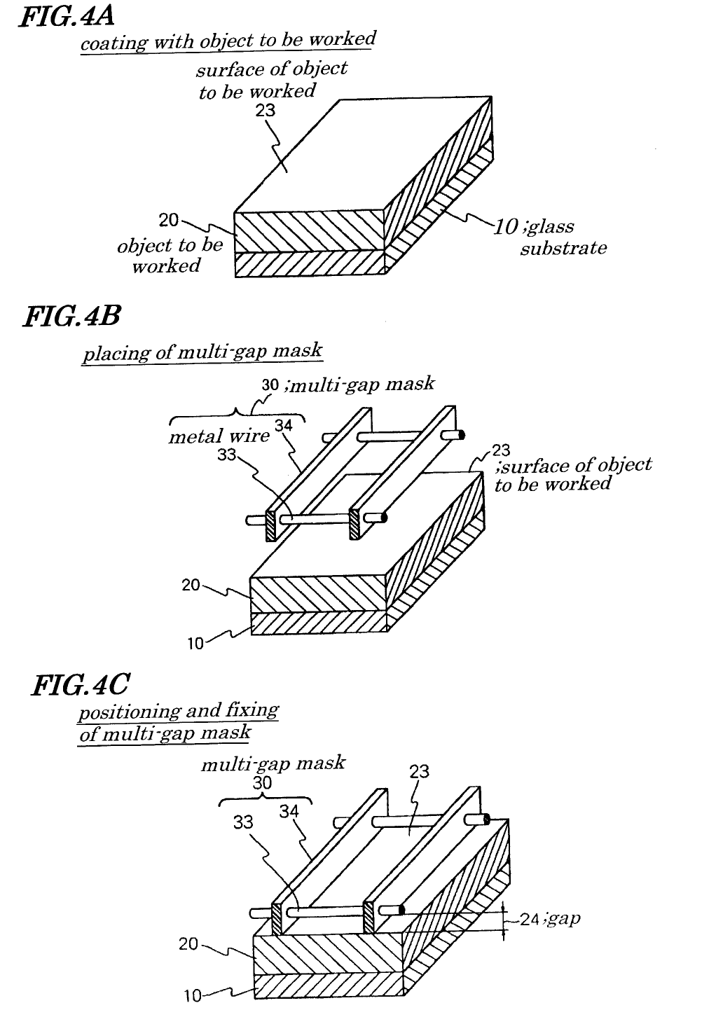

FIGS. 4A, 4B, and 4C are perspective views illustrating a multi-gap mask 30 of the present invention and working methods using the multi-gap mask 30 according to a first embodiment of the present invention. Descriptions are made based on these drawings.

The multi-gap mask 30 of the first embodiment is fixed on a surface of an object to be worked 23 when working is performed on the surface of the object to be worked 23 by a sandblast process, and first and second mask patterns (described later) each having a different gap 24 from the surface of the object to be worked 23 are formed. The first mask pattern (not shown) is made up of a plurality of metal wires 33 being parallel to one another and the second mask pattern (not shown) intersects the metal wires 33 at right angles and is made up of a plurality of photosensitive emulsions 34 having rectangular parallelepiped shapes being parallel to each other. The metal wires 33 are circular in a cross section and are respectively 150 μm diameter. The gap 24 between the metal wires 33 and a surface of an object to be worked 23 is 200 μm which exceeds a vortex region length.

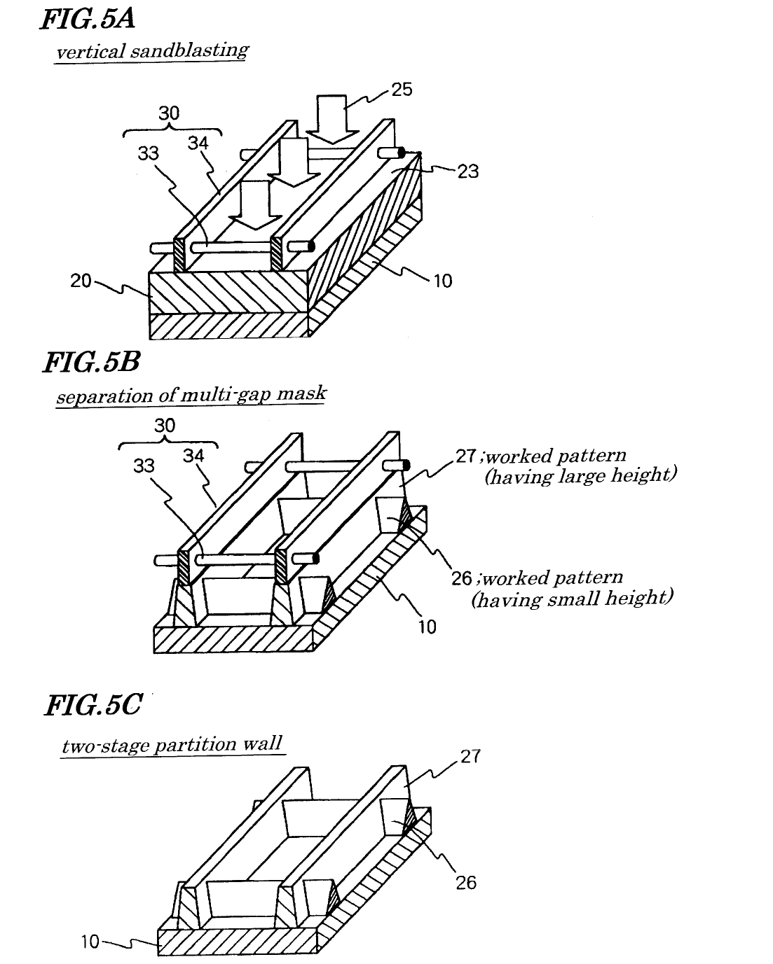

In the working method of the embodiment, calcium carbonate is used as an abrasive compound for sandblasting and a mixed paste made up of mixture of a glass and a filler is used as an object to be worked 20, and polishing work is performed on a surface of the object to be worked 23 by sending a blast of an abrasive compound 25 (FIG. 5A) from a vertical direction to form a worked pattern 26 (FIG. 5B) having a small height and a worked pattern 27 (FIG. 5C) having a large height.

First, a glass substrate 10 is coated with the object to be worked 20 and is then dried (FIG. 4A). Next, the multi-gap mask 30 is placed on a surface of the object to be worked 23 (see FIG. 4B). Then, after positioning has been performed using a cross marker (not shown) carved in the glass substrate 10 and the multi-gap mask 30, the multi-gap mask 30 is fixed on the surface of the object to be worked 23 by using a vacuum chuck (FIG. 4C). Next, the polishing work by sandblasting is performed on the surface of the object to be worked 23 from a vertical direction (FIG. 5A). Then, the multi-gap mask 30 is released from the vacuum chuck, whereby the surface of the object to be worked 23 and the multi-gap mask 30 is separated from each other (FIG. 5B). This causes the worked pattern 26 having a small height and the worked pattern 27 having a large height to be formed and a two-stage type partition wall to be completed (FIG. 5C). A shape of a cross section of the worked pattern 26 having a small height is an isosceles triangle and a shape of a cross section of the worked pattern 27 having a large height is an isosceles trapezoid.

Moreover, in the embodiment, calcium carbonate is used as the abrasive compound 25 and a mixed paste of glass and a filler is used as the object to be worked 20, however, the present invention is not limited to the combination of the abrasive compound 25 and the object to be worked 20. A shape of the cross section of the metal wires 33 may be half-round, rectangular, and triangular. Also, instead of sandblasting, a liquid honing technique may be used. The liquid honing represents technology by which a blast of a liquid obtained by mixing the abrasive compound with water is sent on an object to be worked 20, together with compressed air, from a nozzle to perform working on the object to be worked 20. A shape of the cross section of the worked pattern 26 having a small height may be M-shaped or trapezoidal by reducing an interval between adjacent metal wires 33 in the multi-gap mask 30. A material for the metal wires 33 is not limited to metal materials such as SUS (Special Use Stainless Steel) stainless steel, stainless steel, copper, brass, and a like, but may be non-metal materials such as Kevlar (aramid fiber), carbon, or a like. Moreover, in the embodiment, a working depth may be of two types, however, may be of three types.

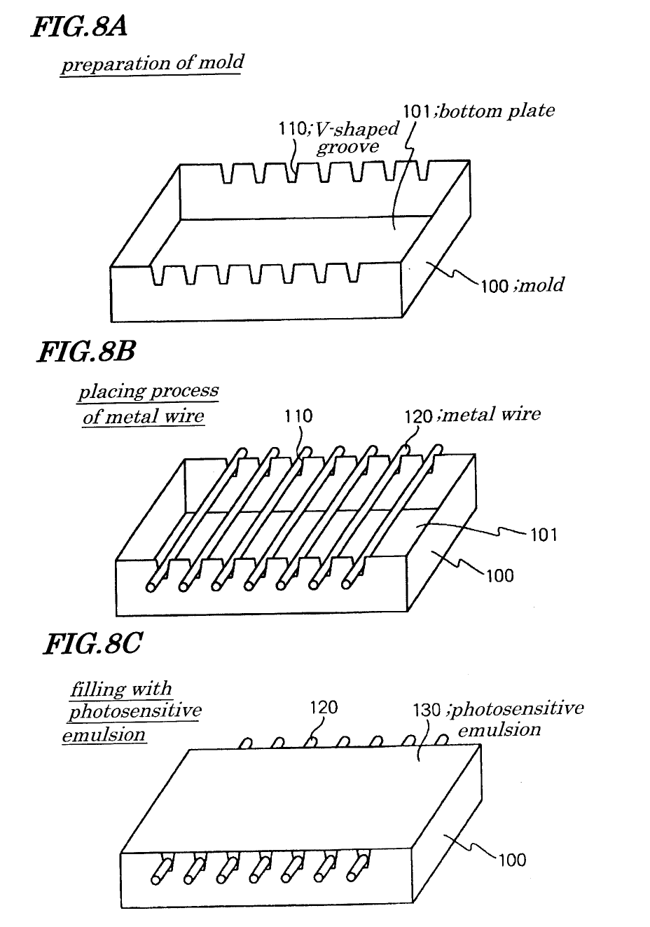

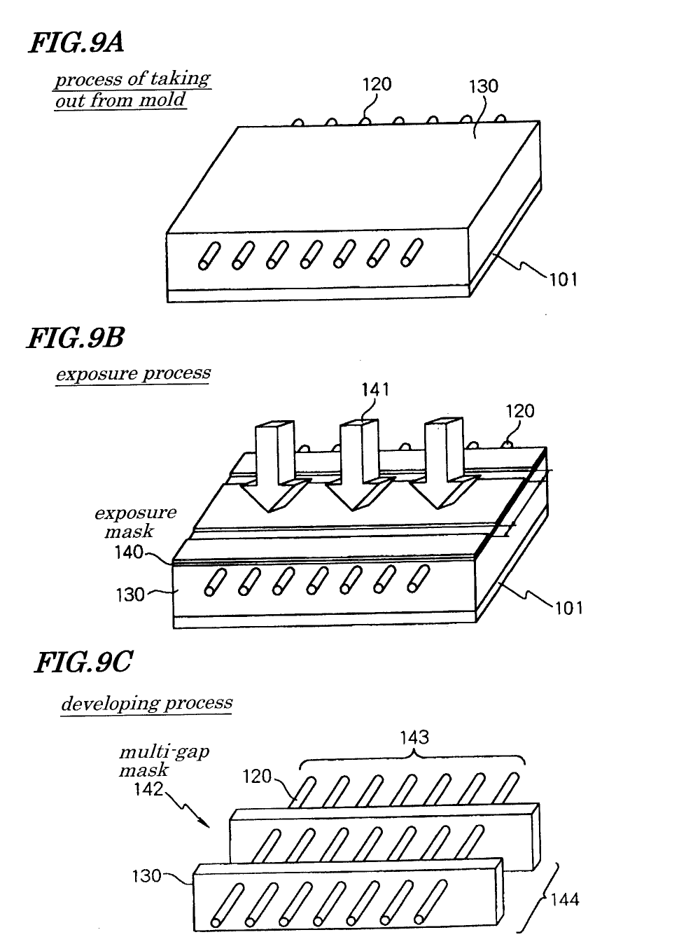

FIGS. 8A, 8B, and 8C and FIGS. 9A, 9B, and 9C are perspective views illustrating a method of manufacturing a multi-gap mask 142 according to the first embodiment of the present invention. Descriptions are made by referring to these drawings.

First, a bottomless mold 100 having a plurality of V-shaped grooves 110 and a movable bottom plate 101 are prepared for positioning and fixing of metal wires 120. Then, the metal wires 120 are stretched through the V-shaped grooves 110 of the mold 100 (FIG. 8B). Next, a photosensitive emulsion 130, after having been poured into the mold 100, is dried and hardened (FIG. 8C).

Then, the photosensitive emulsion 130, together with the bottom plate 101 is taken out from the mold 100. Next, after an exposure mask 140 (FIG. 9B) has been placed on the photosensitive emulsion 130 (FIG. 9A), an ultraviolet ray 141 is applied through the exposure mask 140 to the photosensitive emulsion 130 and a latent image is formed in the photosensitive emulsion 130 (FIG. 9B). Finally, by developing the photosensitive emulsion 130 using hydrogen peroxide (oxyful), the multi-gap mask 142 is obtained (FIG. 9c).

The multi-gap mask 142 is provided with a mask pattern 143 made up of a plurality of metal wires 120 being parallel to each other and a mask pattern 144 made up of a plurality of the rectangular-parallelepiped-shaped photosensitive emulsions 130 intersecting the metal wires 120 at right angles and being parallel to each other.

In the embodiment, SUS stainless steel is used for the mold 100, a glass substrate is used for the bottom plate 101, diazo emulsion is used as the photosensitive emulsions 130, and a plurality of copper wires respectively with a diameter of 150 μm is used for the metal wires 120. As the exposure mask 140, an emulsion mask having a stripe pattern is used. Moreover, in the embodiment, exposure is performed only from one face, however, after the exposure mask 140 has been placed on both an upper surface and lower surface of the photosensitive emulsion 130, a latent image maybe formed in the photosensitive emulsion 130 by applying the ultraviolet ray 141.

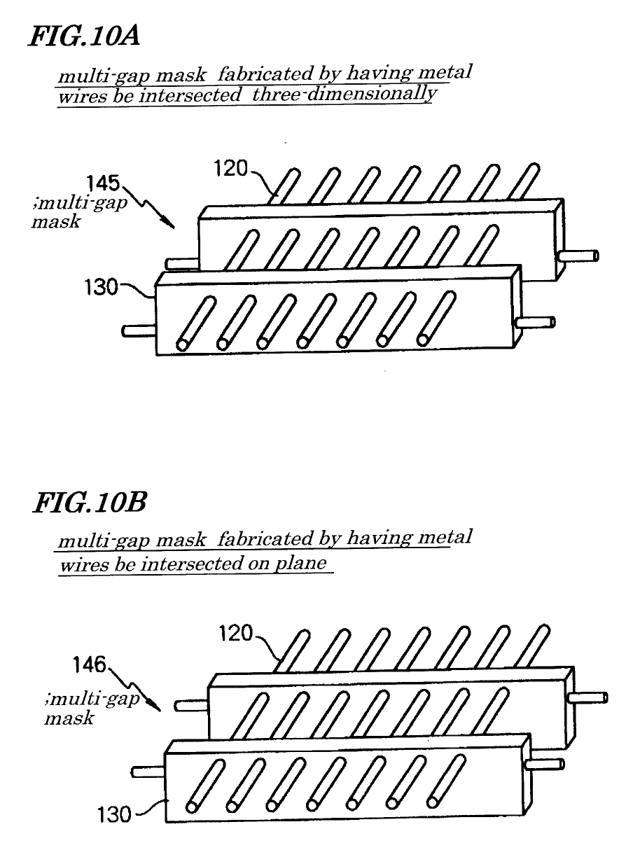

FIGS. 10A and 10B are perspective views showing an other example of the multi-gap masks 145, 146 employed in the first embodiment provided in FIGS. 8A, 8B, and 8C and FIGS. 9A, 9B, and 9C. Descriptions are made by referring to the above drawings.

A multi-gap mask 145 shown in FIG. 10A is fabricated by having two groups of the metal wires 120 intersect each other at right angles and at multi-grade. Whereas, a multi-gap mask 146 shown in FIG. 10B is fabricated by having two groups of the metal wires 120 intersect each other at grade. In any case, since mechanical strength increases by having the metal wires 120 intersect the photosensitive emulsion 130, a life of each of the multi-gap masks 145, 146 becomes long and a dimensional accuracy is improved.

### Second Embodiment

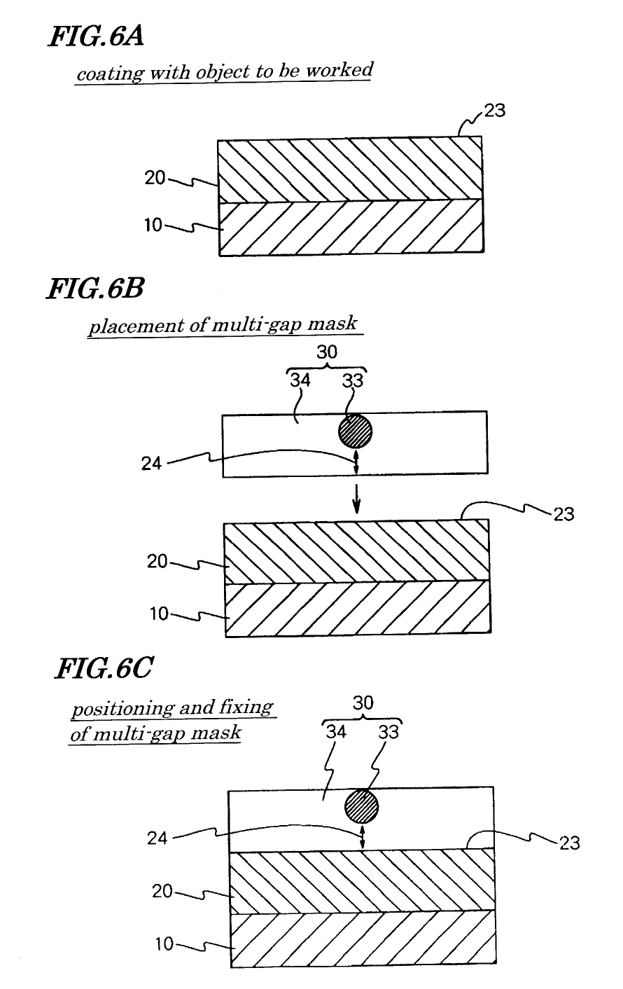

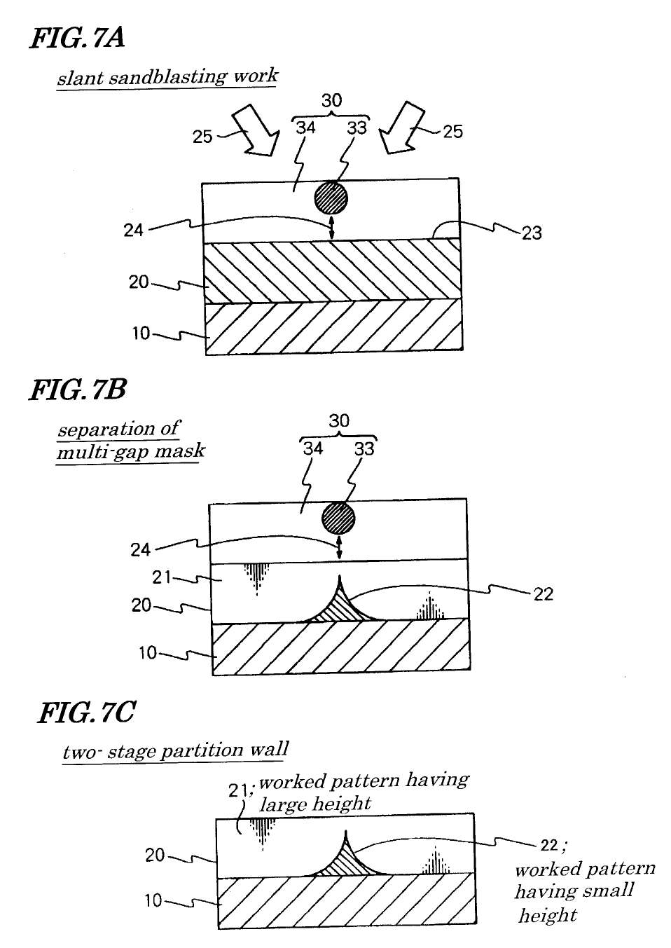

FIGS. 6A, 6B, and 6C and FIGS. 7A, 7B, and 7C are cross-sectional views illustrating a multi-gap mask 30 of the present invention and a working method using the same according to a second embodiment of the present invention. Descriptions of the embodiment will be made by referring to drawings. In FIGS. 4A to 4C and FIGS. 5A to 5C, same reference numbers are assigned to parts having same functions and descriptions of them will be omitted.

In the multi-gap mask 30 of the embodiment, a gap 24 between a metal wire 33 and a surface of an object to be worked 23 is 40 μm which is less than the vortex region length. In the working method of the embodiment, a polishing process is performed by sending, to the surface of the object to be worked 23, a blast of an abrasive compound 25 from two directions being tilt by ±15 degrees relative to a vertical direction with being shifted in time to form a worked pattern 21 having a large height and a worked pattern 22 having a small height.

First, a glass substrate 10 is coated with an object to be worked 20 and the coated object to be worked 20 is dried (FIG. 6A). Then, the multi-gap mask 30 is placed on the surface of the object to be worked 23 (FIG. 6B). Then, after positioning has been performed using a cross marker (not shown) carved in the glass substrate 10 and the multi-gap mask 30, the multi-gap mask 30 is fixed on the surface of the object to be worked 23 by using a vacuum chuck (FIG. 6C).

Then, a polishing process by sandblasting is performed on the surface of the object to be worked 23 from right and left slant directions (FIG. 7A). Next, the multi-gap mask 30 is released from the vacuum chuck, whereby the surface of the object to be worked 23 and the multi-gap mask 30 is separated from each other (FIG. 7B). This causes the worked pattern 21 having a large height and the worked pattern 22 having a small height to be formed and a two-stage type partition wall to be completed (FIG. 7C). At this point, a shape of a cross section of the worked pattern 22 having a small height is an isosceles triangle and its slant surface is a curve.

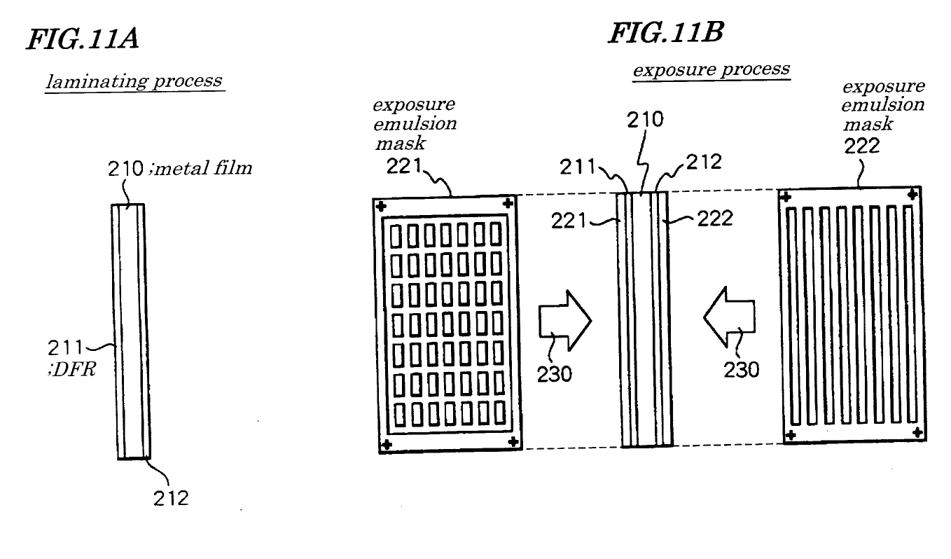

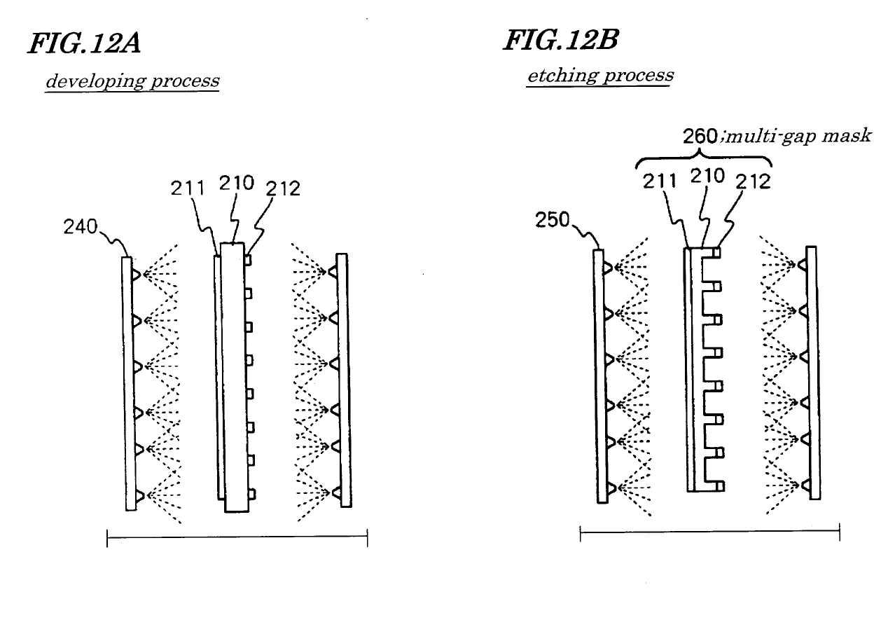

FIGS. 11A and 11B and FIGS. 12A and 12B are diagrams schematically illustrating a method for manufacturing a multi-gap mask according to the second embodiment. Descriptions are made by referring to the above drawings.

In the embodiment, a method for manufacturing the multi-gap mask by performing etching on a metal film is provided. First, DFRs 211 and 212 in NIT 625 manufactured by Nihon Synthetic Chemical Ltd., being a resist which enables alkaline development and has a resistance to acids are laminated on both sides of a metal film 210 made of SUS stainless steel (with a thickness of 0.3 mm) (see FIG. 11A). Next, an exposure emulsion mask 221 with a pitch of a longitudinal stripe of a mesh of 0.27 mm, with a width of the longitudinal stripe of the mesh of 0.07 mm, with a pitch of a horizontal stripe of 0.54 mm and with a width of the horizontal stripe of 0.15 mm and an exposure emulsion mask 222 with a pitch of a longitudinal stripe of 0.27 mm and with a width of a longitudinal stripe of 0.07 mm are prepared. Then, exposure is performed on the DFRs 211 and 212 by applying an ultraviolet ray 230 through the exposure emulsion masks 221 and 222 (see FIG. 11B)

Then, a developing solution made of an aqueous solution of sodium carbonate is sprayed on the DFRs 211 and 212 by using a spray-type developing machine 240. This causes the DFR 211 having a mesh pattern and the DFR 212 having a stripe pattern to be formed on both sides of the metal film 210 (see FIG. 12A). Next, by using a spray-type etching apparatus 250, etchant made of an aqueous solution of hydrochloric acid is sprayed on both sides of the metal film 210 through the DFRs 211 and 212. By the etching process, a mesh portion of one surface of the mesh and a horizontal stripe portion of another surface of the mesh are removed. By using the mesh portion as a through hole and by performing half-etching on the horizontal stripe portion, a longitudinal stripe pattern and a horizontal stripe pattern each having a different thickness is formed. By this, a multi-gap mask 260 can be obtained (see FIG. 12B). At this point, DFR patterns being left may be removed by a stripping solvent or may be used, by having it be left as it is, as a protective film serving as a sandblast-proof member (not shown).

By the above manufacturing method, a multi-gap mask 260 with a thickness of the longitudinal stripe of the metal mesh of 0.3 mm, with a thickness of the horizontal stripe pattern of 0.1 mm and with a gap from a surface of an object to be worked of 0.2 mm is fabricated. According to the method for manufacturing the multi-gap mask 260 of the embodiment, a difference in thickness between the longitudinal stripe pattern and the horizontal stripe pattern can be calibrated based on the thickness of the metal film 210 and an amount of etching.

Moreover, in the embodiment, etching is performed on both sides of the metal film 210 at a same time, however, the etching may be performed alternately on one side and another side of the metal film 210 or the etching may be performed first on both sides of the metal film 210 at a same time and then, after a depth of etching on one side of the metal film 210 has reached a set amount, by stopping the etching on one side of the metal film 210, the etching may be performed on another side of the metal film 210. The metal film 210 may be a monolayer film made of stainless steel, 42 alloy, 426 alloy, copper, copper alloy, iron, alloy of iron and nickel, aluminum, or a like, or may be multilayer film made of various metal. Moreover, instead of the metal film 210, an organic material may be used so long as a material can be etched. Instead of the DFRs 211 and 212, a liquid resist may be used.

### Third Embodiment

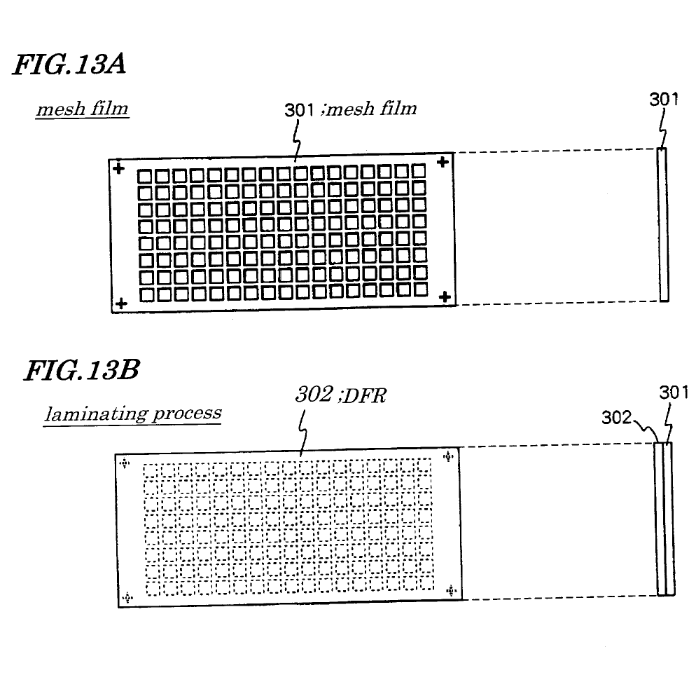

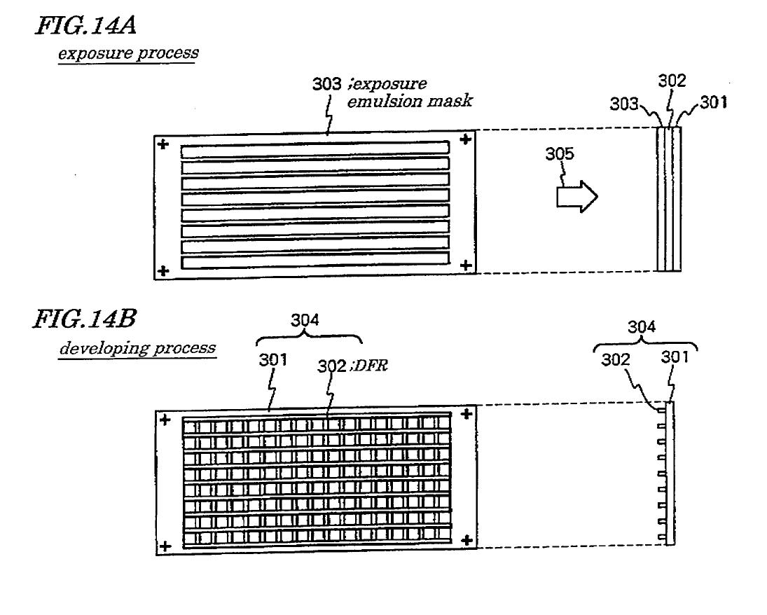

FIGS. 13A and 13B and FIGS. 14A and 14B are plan views and right side views illustrating a method for manufacturing a multi-gap mask according to a third embodiment of the present invention. Descriptions are made by referring to the above drawings.

In the embodiment, a method for manufacturing the multi-gap mask by having a resist layer be formed on a mesh film prepared in advance and forming a stripe pattern by exposure and development. First, a mesh film 301 is prepared by forming a DFR of a mesh pattern on both sides of the mesh films 301 and performing etching (FIG. 13A). Next, a DFR 302 with a thickness being equivalent to a gap from a surface of an object to be worked is stuck to one side of the mesh film 301 (FIG. 13B).

Then, exposure is performed on the DFR 302 by applying an ultraviolet ray 305 to the DFR 302 through an exposure emulsion mask 303. This causes a stripe-shaped latent image to be formed (FIG. 14A). Finally, a multi-gap mask 304 is finished by developing the DFR 302 (FIG. 14B). According to the embodiment, only by changing a thickness of the DFR 302, a gap from a surface of an object to be worked can be easily calibrated.

In the embodiment, a mesh film 301 is prepared by using SUS stainless steel 304 with a thickness of 0.15 mm as the film and by an exposure emulsion mask with a pitch of a longitudinal stripe of a mesh of 0.27 mm, with a width of the longitudinal of 0.07, with a pitch of a horizontal stripe of 0.54 mm and with a width of the horizontal stripe of 0.15 mm. Moreover, two kinds of the DFR 302 are prepared, one using one piece of the DFR of APD-401 manufactured by Asahi Chemical Ltd., which provides a thickness of 40 μm and another using five pieces of the DFR which provides a thickness of 200 μm. The exposure emulsion mask 303 has a pitch of the longitudinal stripe of 0.27 mm and a width of the longitudinal stripe of 0.07 mm. In the developing process, a spray-type developing machine adapted to spray an aqueous solution of sodium carbonate is used.

Thus, according to the present invention, three-dimensional mask patterns a part or a whole of each of which is in non-contact with the surface of the object to be worked and which are provided with space where gaps (that is, distances) between the surface of the object to be worked and the mask pattern are different from each other is used. Polishing work is performed by placing the multi-gap mask 304 on the surface of the object to be worked and by sending a blast of a viscous fluid to the surface of the object to be worked from a vertical or slant direction on the three dimensional mask pattern. According to the present invention, it is possible to form a pattern worked object having at least two worked patterns each having a different height and a shape of at least one worked pattern being triangular.

Moreover, since, by using the multi-gap mask 304 for sandblasting, patterns each having a different height can be formed in a concurrent manner and, since the sticking of the DFR 302 to the object to be worked, exposure process, development, peeling process, which were needed in the conventional sandblasting work, are not required, reduction of costs can be made possible.

It is apparent that the present invention is not limited to the above embodiments but may be changed and modified without departing from the scope and spirit of the invention.

What is claimed is:

1. A multi-gap mask comprising:
at least two mask patterns to be fixed on a surface of an object to be worked while working is performed on said surface of said object to be worked by sending a blast of a viscous fluid including an abrasive compound and each having a different gap from said surface of said object to be worked.

2. The multi-gap mask according to claim 1, wherein at least one of at least two mask patterns has the gap being zero from said surface of said object to be worked.

3. The multi-gap mask according to claim 1, comprising first and second mask patterns each having said different gap wherein said first mask pattern has a shape of a plurality of straight lines being parallel to one another and wherein said second mask pattern intersects said first mask pattern and has a shape of a plurality of straight lines being parallel to one another.

4. The multi-gap mask according to claim 3, wherein a whole or a part of shapes having said plurality of said straight lines is of a circular cylindrical shape.

5. A method for manufacturing component part by using a multi-gap mask comprising at least two mask patterns each having a different gap from a surface of an object to be worked, said method comprising:
a step of fixing said multi-gap mask on said surface of said object to be worked;
a step of performing work on said surface of said object to be worked by sending a blast of a viscous fluid including an abrasive compound; and
a step of using a vortex region of said viscous fluid occurring on a side of said surface of said object to be worked of said multi-gap mask when working is performed on said surface of said object to be worked.

6. The method for manufacturing component part by using the multi-gap mask according to claim 5, wherein at least one of at least two mask patterns making up said multi-gap mask has the gap being zero from said surface of said object to be worked.

7. The method for manufacturing component part by using the multi-gap mask according to claim 5, wherein said multi-gap mask is made up of first and second mask patterns each having said different gap wherein said first mask pattern has a shape of a plurality of straight lines being parallel to one another and wherein said second mask pattern intersects said first mask pattern and has a shape of a plurality of straight lines being parallel to one another.

8. The method for manufacturing component part by using the multi-gap mask according to claim 7, wherein a whole or a part of shapes having said plurality of said straight lines is of a circular cylindrical shape.

9. The method for manufacturing component part by using the multi-gap mask according to claim 5, wherein said blast of said viscous fluid is sent to said surface of said object to be worked in a slant manner when working is performed on said surface of said object to be worked.

10. A method for manufacturing a multi-gap mask comprising at least two mask patterns each having a different gap from a surface of an object to be worked, said method comprising:
a step of stretching wires having a set height and direction in a photosensitive emulsion;
a step of forming a three-dimensional mask pattern by performing a drying process, exposure process, and developing process on said photosensitive emulsion.

11. The method for manufacturing the multi-gap mask according to claim 10, wherein at least one of at least two mask patterns making up said multi-gap mask has the gap being zero from said surface of said object to be worked.

12. The method for manufacturing the multi-gap mask according to claim 10, wherein said multi-gap mask is made up of first and second mask patterns each having said different gap wherein said first mask pattern has a shape of a plurality of straight lines being parallel to one another and wherein said second mask pattern intersects said first mask pattern and has a shape of a plurality of straight lines being parallel to one another.

13. The method for manufacturing the multi-gap mask according to claim 10, wherein a whole or a part of shapes having said plurality of said straight lines is of a circular cylindrical shape.

14. A method for manufacturing a multi-gap mask comprising at least two mask patterns each having a different gap from a surface of an object to be worked, said method comprising:
a step of sticking a dry film photoresist on both sides of a film;
a step of performing exposure and development on each of said dry film photoresists to produce a different pattern; and
a step of forming a three-dimensional mask pattern by performing etching on said film using said dry film photoresists as a mask.

15. The method for manufacturing the multi-gap mask according to claim 14, wherein at least one of at least two mask patterns making up said multi-gap mask has the gap being zero from said surface of said object to be worked.

16. The method for manufacturing the multi-gap mask according to claim 14, wherein said multi-gap mask is made up of first and second mask patterns each having said different gap wherein said first mask pattern has a shape of a plurality of straight lines being parallel to one another and wherein said second mask pattern intersects said first mask pattern and has a shape of a plurality of straight lines being parallel to one another.

17. The method for manufacturing the multi-gap mask according to claim 14, wherein a whole or a part of shapes having said plurality of said straight lines is of a circular cylindrical shape.

18. A method for manufacturing a multi-gap mask comprising at least two mask patterns each having a different gap from a surface of an object to be worked, said method comprising:
a step of forming a photoresist film on a mesh film; and
a step of forming a three-dimensional mask pattern by performing exposure and development on said photoresist film using a straight-line shaped mask pattern.

19. The method for manufacturing the multi-gap mask according to claim 18, wherein at least one of at least two mask patterns making up said multi-gap mask has the gap being zero from said surface of said object to be worked.

20. The method for manufacturing the multi-gap mask according to claim 18, wherein said multi-gap mask is made up of first and second mask patterns each having said different gap wherein said first mask pattern has a shape of a plurality of straight lines being parallel to one another and wherein said second mask pattern intersects said first mask pattern and has a shape of a plurality of straight lines being parallel to one another.

21. The method for manufacturing the multi-gap mask according to claim 18, wherein a whole or a part of shapes having said plurality of said straight lines is of a circular cylindrical shape
